(19) United States
(12) Patent Application Publication
(10) Pub. No.: US 2012/0080687 A1
(43) Pub. Date: Apr. 5, 2012

(54) NITRIDE SEMICONDUCTOR DEVICE

(75) Inventor: Masahiko KURAGUCHI, Kanagawa (JP)

(73) Assignee: KABUSHIKI KAISHA TOSHIBA, Tokyo (JP)

(21) Appl. No.: 13/075,736

(22) Filed: Mar. 30, 2011

(30) Foreign Application Priority Data
Sep. 30, 2010 (JP) 2010-223173

(51) Int. Cl. H01L 29/20

(52) U.S. Cl. 257/76; 257/E29.089

(57) ABSTRACT

A nitride semiconductor device of an embodiment includes: a nitride semiconductor device, including: a nitride semiconductor substrate; a first anode electrode formed on the substrate; a recess structure formed on the substrate of an outer peripheral portion of the first anode electrode by engraving the substrate; a second anode electrode formed so as to cover the first anode electrode and so as to be embedded in the recess structure; and a cathode electrode formed on the substrate.

### CROSS-REFERENCE TO RELATED APPLICATION

This application is based upon and claims the benefit of priority from Japanese Patent Applications No. 2010-223173, filed on Sep. 30, 2010; the entire contents of which are incorporated herein by reference.

### FIELD

Embodiments described herein relate generally to a nitride semiconductor device.

### BACKGROUND

In order to realize a high output, high breakdown voltage, and a low on-resistance in a semiconductor device, it is effective to use a material having a high critical electric field. Since the nitride semiconductor has a high critical electric field strength, the semiconductor device, which realizes the high output, the high breakdown voltage, and the low on-resistance may be obtained by using the nitride semiconductor.

In the nitride semiconductor device, by depositing a GaN film as a carrier transit layer 1 and an AlₓGa_{1-X}N (0<X≦1) film as a barrier layer 2, a strain is generated in the barrier layer 2 since a lattice constant of the AlN film is smaller than that of the GaN film and the lattice constant is smaller in the barrier layer 2. In the nitride semiconductor, a two-dimensional electron system is generated in the interface between the carrier transit layer 1 and the barrier layer 2 by piezo polarization in association with the strain of the barrier layer 2 and spontaneous polarization. Therefore, by forming a cathode electrode ohmically connected on the nitride semiconductor and an anode electrode Schottky connected to the nitride semiconductor, a nitride semiconductor diode may be realized.

As a method of realizing the diode whose on-resistance is low and whose reverse leak current is low, a method of forming the anode electrode of two types of electrodes whose work functions are different from each other is known. At the time of forward operation, a current flows through an electrode unit whose work function of the anode electrode is small, so that the on-resistance is low, and at the time of reverse operation, it is depleted from under the electrode unit whose work function of the anode electrode is large, so that a reverse low leak current may be realized. A method of forming a fluorine-incorporated region on a part under the anode electrode is also known. At the time of the reverse operation, it is depleted from under the fluorine-incorporated region, so that the reverse low leak current may be realized.

### BRIEF DESCRIPTION OF THE DRAWINGS

FIG. 1 is a schematic cross-sectional view of a cross-sectional structure of a semiconductor device according to a first embodiment;

FIG. 2 is a view which compares reverse leak currents of a recess structure and of a structure other than the recess structure in the embodiment when applying negative bias;

FIG. 3 is a schematic view of a band structure when applying in the embodiment;

FIG. 4 is a view which compares on-currents of the recess structure and of a structure other than the recess structure in the embodiment when applying positive bias;

FIG. 5 is a diagram in which a threshold voltage at which a two-dimensional electron system is depleted is plotted against an Al composition ratio X of a barrier layer 2 and a film thickness of the barrier layer 2 in the embodiment;

FIG. 6 is a cross-sectional view of a first modification of the semiconductor device according to the first embodiment;

FIG. 7 is a cross-sectional view of a second modification of the semiconductor device according to the first embodiment;

FIG. 8 is a schematic top view of a bird eye's view of the semiconductor device according to the first embodiment;

FIG. 9 is a cross-sectional view of the semiconductor device according to a second embodiment;

FIG. 10 is a cross-sectional view of a modification of the semiconductor device according to the second embodiment;

FIG. 11 is a top view of the semiconductor device according to a third embodiment; and

FIG. 12 is a top view of a modification of the semiconductor device according to the third embodiment.

### DETAILED DESCRIPTION

A nitride semiconductor of an embodiment includes: a nitride semiconductor substrate; a first anode electrode formed on the substrate; a recess structure formed on the substrate of an outer peripheral portion of the first anode electrode by engraving the substrate; a second anode electrode formed so as to cover the first anode electrode and so as to be embedded in the recess structure; and a cathode electrode formed on the substrate.

Embodiments of the invention will be described below with reference to the drawings.

### First Embodiment

A nitride semiconductor device, including: a nitride semiconductor substrate; a first anode electrode formed on the substrate; a recess structure formed on the substrate of an outer peripheral portion of the first anode electrode by engraving the substrate; a second anode electrode formed so as to cover the first anode electrode and so as to be embedded in the recess structure; and a cathode electrode formed on the substrate. In the device, both of threshold voltages at which a two-dimensional electron system of the first anode electrode and the second anode electrode is depleted are negative values, and the threshold voltage of the second anode electrode is larger than the threshold voltage of the first anode electrode. In the device, the substrate is formed of a GaN layer and a non-doped or n-type AlₓGa₁₋ₓN layer on the GaN layer, and the first anode electrode, the second anode electrode, the recess structure, and the cathode electrode are formed on the AlₓGa₁₋ₓN layer in which 0<x≦1 is satisfied. In the device, the first anode electrode is formed of any metal of Al, Ti, Au, Pd and Ni or an alloy of the metals or a compound of the metals and Si, W and Ta, and the second anode electrode is formed of any metal of Pd, Ni and Pt or an alloy of the metals or a compound of the metals and Si, W and Ta.

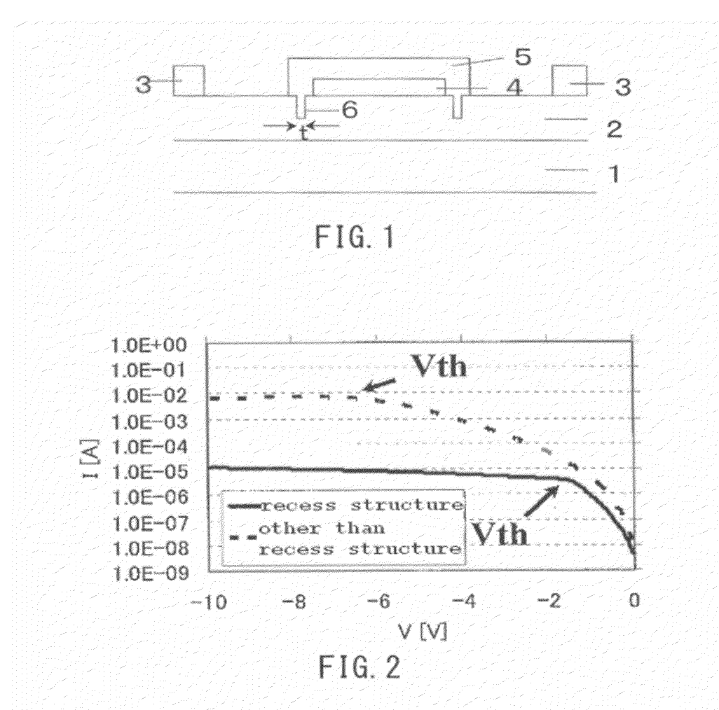

The semiconductor device according to a first embodiment illustrated in FIG. 1 is such that a cathode electrode 3 ohmically connected to a nitride semiconductor and a first and a second anode electrodes 4 and 5 are formed on the nitride semiconductor obtained by depositing a carrier transit layer 1 made of a GaN layer and a barrier layer 2 made of a non-doped or n-type AlₓGa_{1-X}N (0<X≦1) formed on the carrier transit layer 1. The first anode electrode 4 and the second anode electrode 5 are electrically connected to each other. A part of the barrier layer 2 under the second anode electrode 5 is selectively removed to form a recess structure 6. The second anode electrode 5 is embedded in the recess structure 6. The second anode electrode 5 is formed of a metal having a work function higher than the work function of a metal which forms the first anode electrode 4. Although the second anode electrode is Schottky connected to the nitride semiconductor, the first anode electrode is Schottky connected or ohmically connected to the nitride semiconductor.

When positive bias is applied to the anode electrode in the semiconductor device according to the first embodiment illustrated in FIG. 1, this serves as a diode with a low on-voltage by the first anode electrode formed of the metal whose work function is smaller. When negative bias is applied to the anode electrode, a two-dimensional electron system under the recess structure 6 of the second anode electrode closer to the cathode electrode is depleted, so that a current may be turned off. In the semiconductor device according to the embodiment, since the recess structure is formed under the second anode electrode 5, it is possible to make a reverse leak current smaller when applying the negative bias.

Next, a function of the recess structure 6 is described. FIG. 2 is a view in which the reverse leak currents of the recess structure and other than the recess structure are compared with each other when applying the negative bias. FIG. 2 is a diagram in which the reverse leak currents are plotted against a voltage applied to the anode electrode based on the cathode electrode. When the recess structure and other than the recess structure are compared with each other, it is understood that reduction in the leak current by approximately triple digits is realized. This is because a threshold voltage at which the two-dimensional electron system is depleted may be realized with a negative value with a small absolute value in the recess structure.

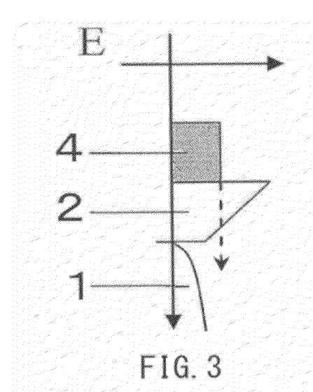

FIG. 3 is a schematic view of a band structure when applying the negative bias. Until the two-dimensional electron system is depleted, the voltage applied to the anode electrode is applied to the barrier layer 2, so that field strength in the barrier layer 2 becomes larger. Therefore, the reverse leak current, which penetrates the barrier layer 2, increases. The reverse leak current exponentially increases up to the threshold voltage at which the two-dimensional electron system is depleted relative to the voltage, as illustrated in FIG. 2. At the threshold voltage or lower, since the two-dimensional electron system under the anode electrode is depleted, the field not lower than this is not applied to the barrier layer 2, so that the reverse leak current has a substantially constant value at the threshold voltage or lower. Therefore, to form the recess structure under the anode electrode and realize the threshold voltage with the negative value with the small absolute value is effective for reducing the reverse leak current.

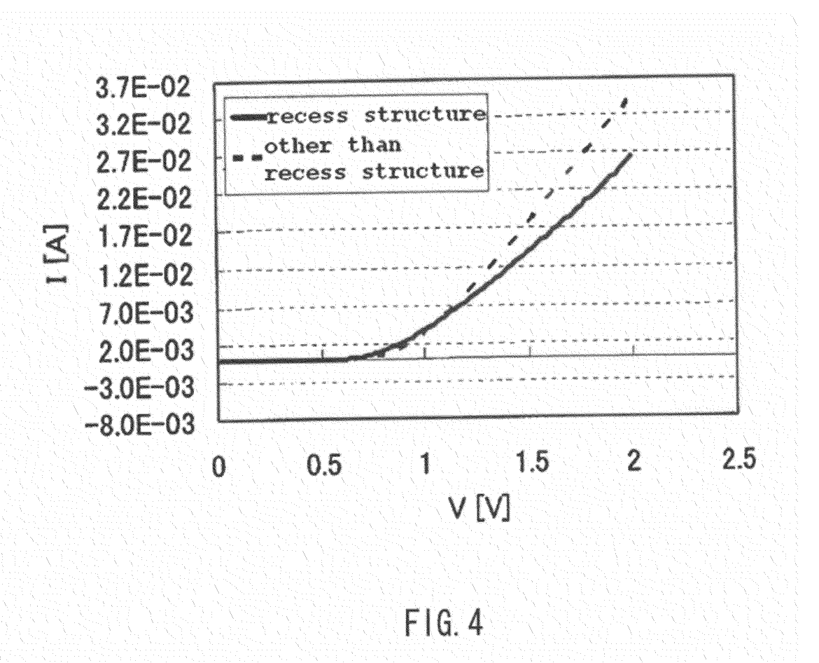

FIG. 4 is a view in which on-currents of the recess structure and other than the recess structure when applying the positive bias are compared with each other. FIG. 4 is a diagram in which the on-currents are plotted against the voltage applied to the anode electrode based on the cathode electrode. When the recess structure and other than the recess structure are compared with each other, the on-current is smaller and on-resistance is larger in the recess structure. This is because a part of the two-dimensional electron system is depleted by the recess structure, thereby increasing the resistance.

As described above, if there is an even recess structure under the anode electrode, the reverse leak current may be reduced. However, the on-current becomes smaller and the on-resistance increases. Therefore, as the semiconductor device according to the first embodiment illustrated in FIG. 1, the recess structure 6 is formed by forming the first anode electrode 4 and the second anode electrode 5 which are electrically connected to each other and by selectively removing a part of the barrier layer 2 under the second anode electrode 5. As a result of this, while a reverse bias leak current is reduced by depletion from under the recess structure when the negative bias is applied, the on-voltage is made lower and the on-resistance is made smaller by applying the current from the first anode electrode 4 when the positive bias is applied. Therefore, it is desired that difference in the work function between the metal, which forms the first anode electrode 4, and the metal, which forms the second anode electrode 5, is larger. At the time of the negative bias, the two-dimensional electron system is depleted from under the second anode electrode, so that the first anode electrode and the nitride semiconductor may be ohmically connected. Comparison of the work functions between various types of metals is illustrated in a table 1. For example, it is possible to use Al, Ti, Au, Pd and Ni with a small work function for the first anode electrode 4 and to use Pd, Ni and Pt with a large work function for the second anode electrode 5. It is also possible to use an alloy thereof, a compound with Si, high-melting-point metal such as W and Ta, and a compound with the high-melting-point metal.

TABLE 1

| | Al | Ti | Au | Pd | Ni | Pt |
|---|---|---|---|---|---|---|
| work function | 4.28 | 4.33 | 5.1 | 5.12 | 5.15 | 5.65 |
| [eV] | | | | | | |

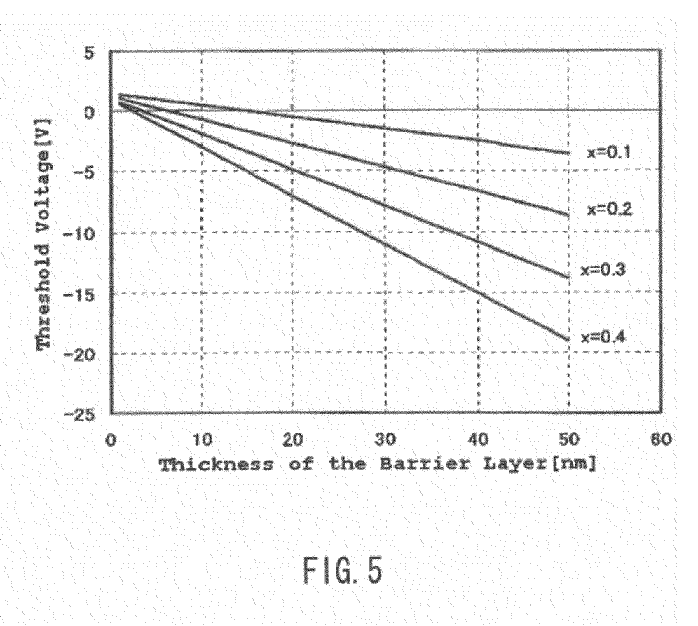

FIG. 5 is a diagram in which the threshold voltage at which the two-dimensional electron system is depleted is plotted against an Al composition ratio X of the barrier layer 2 and a film thickness of the barrier layer 2. In order to inhibit the reverse leak current, to realize the threshold voltage with the negative value with the small absolute value to deplete the two-dimensional electron system under the second anode electrode 5 is effective, so that it is required to realize large difference in the threshold voltage between the first anode electrode and the second anode electrode. For example, although the threshold voltage is approximately −12 V in a case in which the Al composition ratio X of the barrier layer 2 is 0.3 and the film thickness thereof is 40 nm, the threshold voltage under the recess structure is approximately −2 V and the large difference in the threshold voltage of 10 V may be realized when a depth of the recess structure 6 is set to 30 nm and the film thickness of the barrier layer 2 under the recess structure is set to 10 nm. As illustrated in the table 1, the difference in the work function between the various types of metals is up to 1.5 V, and in a case of conventional technology without the recess structure, the difference in the threshold voltage is significantly smaller than that of the semiconductor device according to the embodiment. As illustrated in FIG. 2, since the reverse bias leak current exponentially increases relative to the applied voltage at the threshold voltage or lower, in the semiconductor device according to the embodiment in which the significant difference in the threshold voltage may be realized, an extraordinarily smaller reverse bias leak current may be realized.

In the semiconductor device according to the first embodiment illustrated in FIG. 1, when using the nitride semiconductor obtained by depositing the carrier transit layer 1 made of the GaN layer and the barrier layer 2 made of the non-doped or n-type AlₓGa_{1-X}N (0<X≦1) formed on the carrier transit layer 1, a lattice constant of an AlN film is smaller than that of a GaN film, so that the lattice constant is smaller in the barrier layer 2 and a strain is generated in the barrier layer 2. Therefore, the two-dimensional electron system is generated in the interface between the carrier transit layer 1 and the barrier layer 2 by piezo polarization in association with the strain of the barrier layer 2 and spontaneous polarization, so that concentration of the two-dimensional electron system generated by the polarization may be significantly changed by forming the recess structure.

Therefore, it is effective for significantly generating the threshold voltage difference and significantly reducing the reverse leak current. Although the nitride semiconductor obtained by depositing the AlGaN layer 2 on the GaN layer 1 is used in this embodiment, a semiconductor material obtained by freely combining a composition ratio with AlGaN, InAlN, and GaN may also be used in addition to this. Also, not only a heterojunction but also a super lattice structure, a structure having a plurality of heterojunctions, and a structure with a graded composition may be used as far as the difference in the threshold voltage may be realized.

The semiconductor device according to the first embodiment illustrated in FIG. 1 is also effective for reducing the on-voltage and reducing the on-resistance. As illustrated in FIG. 4, presence or absence of the recess structure does not substantially affect the on-voltage. In a case in which the same Schottky metal is used for the anode electrode, when a composition and doping concentration of a semiconductor surface to which this is Schottky connected are not changed by the presence or absence of the recess structure, Schottky barrier height is not changed. Therefore, in the recess structure also, a positive bias on-current may be applied at the same on-voltage, so that the on-voltage does not increase. It may be said that, since a fluorine-incorporated region has negative charge, the Schottky barrier height increases and the on-voltage of the fluorine-incorporated region increases in the conventional technology with the fluorine-incorporated region, on the other hand, the on-voltage may be inhibited from increasing in the semiconductor device according to the embodiment. Also, a ratio of an effective function of the negative charge, an activation rate, is not necessarily high relative to an amount of incorporated fluorine in the fluorine-incorporated region, and incorporation of fluorine generates a trap, so that there is a problem of delay of dynamic operation; however, the semiconductor device according to the embodiment does not have a structure in which the activation rate is problematic, so that this is advantageous in the dynamic operation.

Also, a part of the on-current flows from the anode electrode 4 through the two-dimensional electron system under the recess structure, it is required to increase the concentration of the two-dimensional electron system under the recess structure. At the time of 0 bias, the concentration of the two-dimensional electron system under the recess structure is lower than that in another anode region; however, capacitance with the two-dimensional electron system is large in the recess structure, an amount of increase in the two-dimensional electron system concentration when applying the positive bias becomes larger than that in another anode region, and the difference in the two-dimensional electron system concentration becomes smaller and sometimes reversed over time. Since the difference in the two-dimensional electron system concentration remains even at the time of the positive bias in the conventional technology without the recess structure, the semiconductor device according to the embodiment is effective for reducing the on-resistance against a problem of the large on-resistance.

As described above, the semiconductor device according to the embodiment may provide the nitride semiconductor device whose on-resistance is small, whose on-voltage is small, and whose reverse leak current is small. Next, a condition in which the semiconductor device according to the embodiment is more effective is described. Although the semiconductor device according to the embodiment significantly inhibits the reverse bias leak current by the recess structure 6, this might decrease the on-current as illustrated in FIG. 4. Therefore, a condition to inhibit the reverse bias leak current without decreasing the on-current and without increasing the on-resistance is described. In the semiconductor device according to the embodiment, a region of the recess structure 6 also carries the on-current when the positive bias is applied. When an entire on-current is applied to the region of the recess structure, the on-current decreases by the recess structure. Therefore, it is required to apply the on-current to a structure other than the recess structure to which a higher current may be applied. By an examination by the inventors, it is obtained that Schottky connection to the nitride semiconductor is such that the Schottky barrier height is approximately 1.3 V and the resistance of a Schottky part is approximately 1.9 Ωmm when using Pt whose work function is large. When using the nitride semiconductor obtained by depositing the carrier transit layer 1 made of the GaN layer and the barrier layer 2 made of the non-doped or n-type AlₓGa_{1-X}N (0<X≦1) formed on the carrier transit layer 1, since it is approximately 480Ω, 1.9 Ωmm/480Ω to 4 μm, and the anode electrode carries the on-current with a width of approximately 4 μm. Therefore, by setting a width t of the recess to 4 μm or smaller, the entire current is not carried only by the recess region and may be applied to another anode electrode, and it becomes possible to inhibit decrease in the on-current by the recess and increase in the on-resistance.

Modification 1 (Modification of First Embodiment)

The nitride semiconductor device according to a modification 1 is different from that of the first embodiment in that a third anode electrode is obtained by integrating the first anode electrode and the second anode electrode, a threshold voltage at which a two-dimensional electron system of a portion on which the recess structure of the third anode electrode is formed is depleted is larger than the threshold voltage at which the two-dimensional electron system of a portion on which a recess structure of the third anode electrode is not formed is depleted, and the both threshold voltages are negative values.

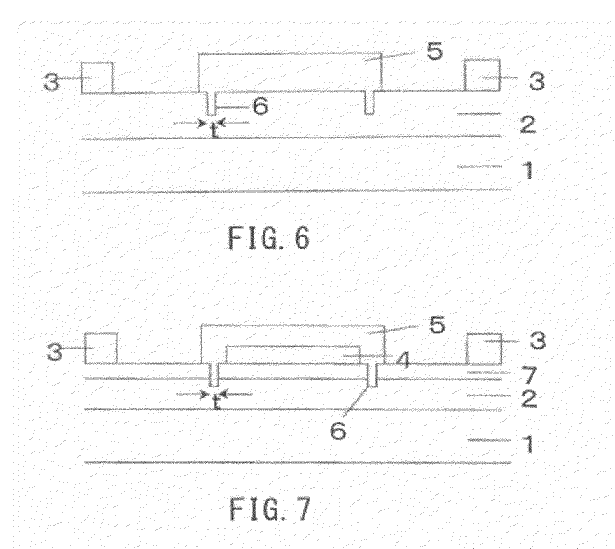

The nitride semiconductor device according to the first modification illustrated in FIG. 6 is different from the semiconductor device according to the first embodiment in that the anode electrode is formed not of two types of anode electrodes but of one type of anode electrode (third anode electrode). In the semiconductor device according to the embodiment, the larger threshold voltage difference may be realized by the recess structure 6 than that by the difference in the types of metals, so that the reverse bias leak current may be significantly reduced without necessarily using two types of metals for the anode electrode. Therefore, it is possible to make a fabrication process simple by using one type of metal.

Second Modification (Modification of First Embodiment)

The nitride semiconductor device according to a second modification is different from that of the first embodiment in that any of a semiconductor layer whose doping concentration is higher than the doping concentration of the AlₓGa₁₋ₓN layer and a semiconductor layer whose Al composition ratio is larger than the Al composition ratio of the AlₓGa₁₋ₓN is provided on the AlₓGa₁₋ₓN layer, the first anode electrode, the second anode electrode, the recess structure, and the cathode electrode are formed on the semiconductor layer, and a bottom portion of the recess structure is formed on the AlₓGa₁₋ₓN layer.

The nitride semiconductor device according to the second modification illustrated in FIG. 7 is different from the semiconductor device according to the first embodiment in that a third nitride semiconductor layer 7 is inserted to the nitride semiconductor layer on a portion above a bottom portion of the recess structure 6. By forming the third nitride semiconductor layer 7 using the nitride semiconductor having the doping concentration larger than that of the barrier layer 2, it is possible to reduce the on-voltage by decreasing the Schottky barrier height of the anode region other than the recess without decreasing the Schottky barrier height of the recess structure and to reduce the on-resistance by decreasing the ohmic resistance of the cathode electrode. Also, by making the Al composition ratio of the third nitride semiconductor layer 7 larger than that of the barrier layer 2, it becomes possible to make the polarization of the region other than the recess structure larger, thereby increasing the two-dimensional electron system concentration. As a result of this, the on-voltage may be reduced and the on-resistance may be reduced by the reduction in the ohmic resistance of the cathode electrode. In addition to this, when a material with the polarization larger than that of the barrier layer 2 is used for the third nitride semiconductor, it is possible to similarly reduce the on-voltage and to reduce the on-resistance by the reduction in the ohmic resistance of the cathode electrode, and it is also possible to use an InGaN layer and an InAlN layer, a layer obtained by mixing or depositing them in addition to the AlGaN layer.

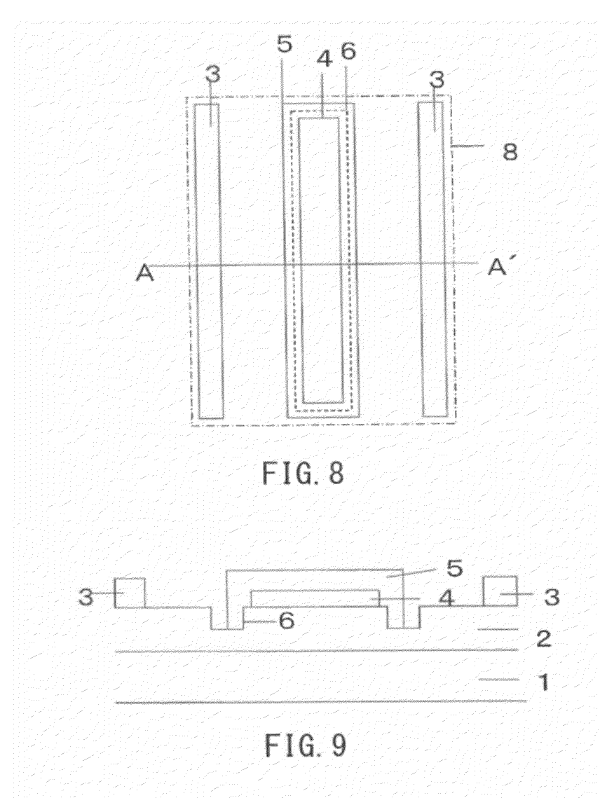

FIG. 8 is a view schematically illustrating a bird's eye view of the semiconductor device according to the first embodiment. FIG. 1 corresponds to a cross-sectional view taken along line A-A′ of FIG. 8. In the semiconductor device according to the first embodiment, the cathode electrode 3 is formed in a device separation region 8 and the anode electrode is formed substantially midway between two cathode electrodes 3. The anode electrode is such that the first anode electrode 4 is formed on a central portion and the second anode electrode 5 is formed so as to protrude outward from the first anode electrode 4. Also, the recess structure 6 is arranged on a peripheral portion so as to enclose an outer side of the anode electrode. By arranging like this, when applying the negative bias to the anode electrode, the two-dimensional electron system under the recess structure 6 of the second anode electrode closer to the cathode electrode is depleted, and as a result of this, the current may be turned off and the reverse bias leak current may be reduced, and when applying the positive bias, it is possible to apply the on-current by the first anode electrode on the central portion, so that the on-voltage may be reduced and the on-resistance may be reduced. Although only a pair of anode electrode and cathode electrodes is illustrated in the semiconductor device according to the first embodiment illustrated in FIG. 8, a plurality of pairs may be arranged in a two-dimensional manner. It is also possible to arrange them not in a rectangular manner as in FIG. 8, but in a square manner, a circular manner, and a hexagonal manner.

### Second Embodiment

The nitride semiconductor device according to a second embodiment is different from that of the first embodiment in that the second anode electrode is formed in a part of the recess structure.

The semiconductor device according to the second embodiment illustrated in FIG. 9 is different from the semiconductor device according to the first embodiment in that the second anode electrode 5 is formed only in a part of the recess and the second anode electrode is not present on a side of the cathode. In the semiconductor device according to the embodiment, the two-dimensional electron system is depleted from the recess structure in which the second anode electrode is formed, so that it is not necessarily required that the second anode electrode is present in an entire recess region and it is only required that the second anode electrode is formed in at least a part of the recess structure.

Third Modification (Modification of Second Embodiment)

The nitride semiconductor device according to a third modification is different from that of the second embodiment in that a plurality of the recess structures are formed.

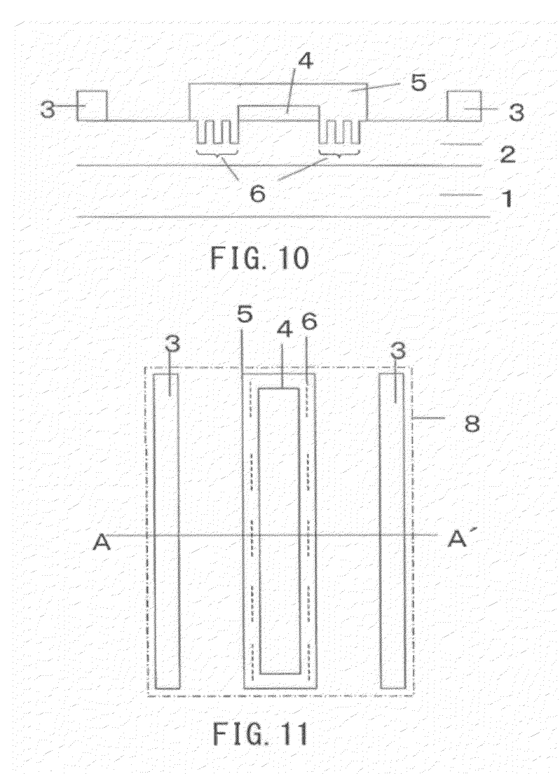

The modification of the semiconductor device according to the second embodiment illustrated in FIG. 10 is different from the semiconductor device according to the first embodiment in that a plurality of recess structures 6 are arranged on the peripheral portion of the second anode electrode 5. In the semiconductor device according to the embodiment, the second anode electrode 5 also carries the on-current, so that it is possible to give preference to the reduction of the on-resistance by dividing the recess structure to increase the region other than the recess structure.

### Third Embodiment

The nitride semiconductor device according to a third embodiment is different from that of the first embodiment in that the recess structure is formed on a part of the outer peripheral portion of the first anode electrode.

The semiconductor device according to the third embodiment illustrated in FIG. 11 is different from the semiconductor device according to the first embodiment in that a part of the recess is broken and is not continuous when the semiconductor device is seen in the bird's eye view. In the semiconductor device according to the embodiment, the depletion of the two-dimensional electron system starts from the recess structure in which the second anode electrode is formed. It is only required that a depleted region is connected at the time of the negative bias, and it is not necessarily required that an entire recess region itself is continuously connected. As a result of this, it becomes possible to carry larger current density by a portion without the recess region at the time of the positive bias, and the on-resistance may be reduced.

Fourth Modification (Modification of Third Embodiment)

The nitride semiconductor device according to a fourth modification is different from that of the third embodiment in that each of the recess structure and the second anode electrode is provided with a protruded portion.

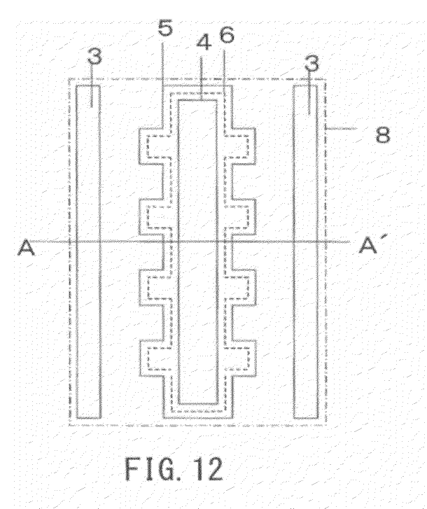

The semiconductor device according to the fourth modification illustrated in FIG. 12 is different in that a part of the anode region protrudes to the cathode region when the semiconductor device is seen in the bird's eye view. The depletion of the two-dimensional electron system starts from the recess structure in which the second anode electrode is formed similarly, the depletion starts also from the protruded region at the time of the negative bias, so that the depleted region is connected between the protruded regions and it is possible to turn the current off. It is possible to carry the larger current density by the portion without the protruded region at the time of the positive bias, thereby reducing the on-resistance.

Thus, by using the fact that the depletion region is spread from the recess structure in which the second anode electrode is formed at the time of the negative bias, it is possible to freely arrange the first anode electrode 4, the second anode electrode 5, and the recess structure 6 in a two-dimensional manner, thereby reducing the on-resistance. According to the semiconductor device according to the embodiment, it is possible to provide the nitride semiconductor device whose on-resistance is small, whose on-voltage is small, and whose reverse leak current is small.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nitride semiconductor device, comprising: a nitride semiconductor substrate; a first anode electrode formed on the substrate; a recess structure formed on the substrate of an outer peripheral portion of the first anode electrode by engraving the substrate; a second anode electrode formed so as to cover the first anode electrode and so as to be embedded in the recess structure; and a cathode electrode formed on the substrate.

2. The device according to claim 1, wherein both of threshold voltages at which a two-dimensional electron system of the first anode electrode and the second anode electrode is depleted are negative values, and the threshold voltage of the second anode electrode is larger than the threshold voltage of the first anode electrode.

3. The device according to claim 1, wherein the substrate is formed of a GaN layer and a non-doped or n-type AlₓGa₁₋ₓN layer on the GaN layer, and the first anode electrode, the second anode electrode, the recess structure, and the cathode electrode are formed on the AlₓGa₁₋ₓN layer in which 0<x≦1 is satisfied.

4. The device according to claim 1, wherein a third anode electrode is obtained by integrating the first anode electrode and the second anode electrode, a threshold voltage at which a two-dimensional electron system of a portion on which a recess structure of the third anode electrode is formed is depleted is larger than the threshold voltage at which the two-dimensional electron system of a portion on which the recess structure of the third anode electrode is not formed is depleted, and the both threshold voltages are negative values.

5. The device according to claim 3, wherein any of a semiconductor layer whose doping concentration is higher than the doping concentration of the AlₓGa₁₋ₓN layer and a semiconductor layer whose Al composition ratio is larger than the Al composition ratio of the AlₓGa₁₋ₓN is provided on the AlₓGa₁₋ₓN layer, the first anode electrode, the second anode electrode, the recess structure, and the cathode electrode are formed on the semiconductor layer, and a bottom portion of the recess structure is formed on the AlₓGa₁₋ₓN layer.

6. The device according to claim 1, wherein the second anode electrode is formed in a part of the recess structure.

7. The device according to claim 1, wherein a plurality of the recess structures are formed.

8. The device according to claim 1, wherein the recess structure is formed on a part of the outer peripheral portion of the first anode electrode.

9. The device according to claim 1, wherein each of the recess structure and the second anode electrode is provided with a protruded portion.

10. The device according to claim 1, wherein the second anode electrode is formed of a material whose work function is higher than the work function of a material which forms the first anode electrode.

11. The device according to claim 8, wherein the first anode electrode is formed of any metal of Al, Ti, Au, Pd and Ni or an alloy of the metals or a compound of the metals and Si, W and Ta, and the second anode electrode is formed of any metal of Pd, Ni and Pt or an alloy of the metals or a compound of the metals and Si, W and Ta.

12. The device according to claim 1, wherein the first anode electrode is Schottky connected or ohmically connected to the substrate.

13. The device according to claim 1, wherein the second anode electrode is Schottky connected to the substrate.

14. The device according to claim 4, wherein the third anode electrode is Schottky connected to the substrate.

15. The device according to claim 1, wherein a width of the recess structure is not larger than 4 μm.

16. The device according to claim 1, wherein a width of the recess structure is not larger than 2 μm.
